(19) United States
(12) Patent Application Publication
(10) Pub. No.: US 2024/0250644 A1
(43) Pub. Date: Jul. 25, 2024

(54) THERMALLY ADJUSTABLE DC BIAS CIRCUITY FOR RF POWER AMPLIFIER WITH REDUCED RF INTERFERENCE

(71) Applicant: Spreadtrum Communications USA Inc., San Jose, CA (US)

(72) Inventor: Jason X Deng, Greensboro, NC (US)

(21) Appl. No.: 18/158,377

(22) Filed: Jan. 23, 2023

(51) Int. Cl. H03F 1/32; H03F 1/30; H03F 3/19

(52) U.S. Cl. CPC H03F 1/32; H03F 1/30; H03F 3/19; H03F 2200/447; H03F 2200/451; H03F 2200/468

(57) ABSTRACT

A circuit includes: an RF amplifier including RF transistor(s); a DC power source electrically coupled to the RF amplifier; a bias control input that receives a bias control signal from a bias control circuit electrically coupled to the DC power source; and a thermal tracking circuit located at a distance from the RF transistor(s) such that RF interference between the RF transistor(s) and the thermal tracking circuit is below a threshold during circuit operation. The thermal tracking circuit includes heating element(s), a DC bias reference device, and a thermal tracking control circuit electrically coupled to the DC power source and the heating element(s). The thermal tracking control circuit generates a signal that controls a thermal behavior of the heating element(s). The heating element(s) heat the DC bias reference device when activated. The DC bias reference device is electrically coupled to the bias control input to modulate a bias voltage.

### BACKGROUND

In wireless communication devices, a radio frequency (RF) front end module processes modulated RF signals that are received from an antenna or to be transmitted by an antenna. In the transmission path, an RF front end module often has one or more RF power amplifiers that amplify the power of the RF signals to a level suitable for transmission. Ideally, the output level of an RF power amplifier and the input level of the RF power amplifier manifest a linear relationship in the frequency range of the RF signals. In reality, however, the linearity of an RF power amplifier may be undermined due to various factors.

### SUMMARY

The subject matter disclosed herein relates to thermally-adjustable direct current (DC) bias circuitry for an RF front end module having one or more RF power amplifiers, referred to as RF front end power amplifier module. The DC bias circuitry offers improved RF front end performance. The DC bias circuitry also offers flexibility for circuit designers to adjust the DC control voltage or current applied to RF amplifiers to track the thermal behavior of the RF amplifiers, with minimal RF interference to bias reference device.

In general, in some aspects, the subject matter of the present disclosure can be embodied in a circuit. The circuit includes: an RF amplifier including one or more RF transistors; a DC power source electrically coupled to the RF amplifier; a bias control input that receives a bias control signal from a bias control circuit, where the bias control input is electrically coupled to the DC power source; and a thermal tracking circuit located at a distance from the one or more RF transistors such that RF interference between the one or more RF transistors and the thermal tracking circuit is below a threshold interference during operation of the circuit. The thermal tracking circuit includes one or more heating elements, a DC bias reference device, and a thermal tracking control circuit electrically coupled to the DC power source and to the one or more heating elements. The thermal tracking control circuit generates a thermal tracking control signal that controls a thermal behavior of the one or more heating elements. The one or more heating elements are arranged to heat the DC bias reference device when the one or more heating elements are activated. The DC bias reference device is electrically coupled to the bias control input and configured to modulate a bias voltage of the RF amplifier.

In some implementations, the bias control signal and the thermal tracking control signal are synchronized with a pulse signal.

In some implementations, the one or more heating elements include two or more heating transistors, which may surround the DC bias reference device.

In some implementations, the DC power source is electrically coupled to the RF amplifier via a coupling transistor, which is controlled by the bias control signal.

In some implementations, the DC bias reference device includes a DC bias reference transistor.

In some implementations, the distance is determined based at least on an operating frequency of the RF amplifier, a thermal radiation of the one or more RF transistors, or a size constraint of the circuit.

In some implementations, the bias control circuit is configured to control the DC power source to provide the bias voltage at a predetermined time before the RF amplifier receives an RF signal.

In some aspects, the above-described circuit is included in an apparatus as one of a plurality of amplification stages.

In some aspects, the subject matter of the present disclosure can be embodied in a method for tracking a thermal behavior of an RF amplifier in a circuit. The method includes controlling, via a bias control signal, a DC power source electrically coupled to the RF amplifier. The method includes controlling, via a thermal tracking control signal, the DC power source to supply power to one or more heating elements. The thermal tracking control signal controls a thermal behavior of the one or more heating elements. The method also includes modulating a bias voltage of the RF amplifier based on an output of a DC bias reference device. The one or more heating elements are arranged to heat the DC bias reference device when the one or more heating elements are activated. The DC bias reference device is located at a distance from one or more RF transistors of the RF amplifier such that RF interference between the one or more RF transistors and the DC bias reference device is below a threshold interference during operation of the circuit.

In some implementations, the bias control signal and the thermal tracking control signal are synchronized with a pulse signal.

In some implementations, the one or more heating elements include two or more heating transistors, which may surround the DC bias reference device.

In some implementations, the DC power source is electrically coupled to the RF amplifier via a coupling transistor, which is controlled by the bias control signal.

In some implementations, the DC bias reference device includes a DC bias reference transistor.

In some implementations, the method further includes determining the distance based at least on an operating frequency of the RF amplifier, a thermal radiation of the one or more RF transistors, or a size constraint of the circuit.

In some implementations, the bias control signal controls the DC power source to provide the bias voltage at a predetermined time before the RF amplifier receives an RF signal.

The details of one or more implementations are set forth in the accompanying drawings and the description below. Other features, objects, and advantages of these systems and methods will be apparent from the description and drawings, and from the claims.

### BRIEF DESCRIPTION OF THE DRAWINGS

FIG. 1 is a schematic diagram of an example of a wireless communication system, according to some implementations.

FIG. 2 is a block diagram of example details of a wireless device, according to some implementations.

FIG. 3A is a schematic diagram of an example RF front end power amplifier module with thermal coupling between a power amplifier and a direct current (DC) bias reference device.

FIG. 3B is another schematic diagram of an example RF front end power amplifier module with thermal coupling between a power amplifier and a DC bias reference device.

FIG. 4A is a schematic diagram of an example RF front end power amplifier module with one or more power amplifiers, according to some implementations.

FIG. 4B is a schematic diagram of another example RF front end power amplifier module with one or more power amplifiers, according to some implementations.

FIG. 5 is a flowchart of an example method, according to some implementations.

### DETAILED DESCRIPTION

An RF amplifier, such as an RF power amplifier, can operate in various modes depending on wireless communication technologies. In some technologies that utilize Time Division Duplex (TDD), the RF power amplifier is configured to operate in a pulse mode in which the RF power amplifier is turned on and off very rapidly. In particular, for a bipolar junction transistor (BJT)-based RF power amplifier, a bias control circuit can control a DC power source to supply a bias voltage to one or more BJTs (“RF BJTs” or “RF transistors” hereinafter) of the RF power amplifier, thereby controlling the operation of the RF power amplifier. When the RF power amplifier operates in the pulse mode, the bias voltage quickly increases to a relatively high level at the rising edge of a pulse, and quickly drops to a relatively low level at the falling edge of the pulse.

When the RF BJTs are properly biased, the transfer characteristics of the RF BJTs are expected to be linear, and the RF power amplifier is expected to amplify the input RF signals properly. However, because the pulse mode causes rapid in-flow and out-flow of electric currents to and from the RF BJTs, the RF BJTs' temperature can change drastically between two consecutive pulses. The change of temperature can lead to changes of physical properties of the RF BJTs, causing the transfer characteristics of the RF BJTs to shift. As a result, the RF power amplifier can experience degraded linearity, which further leads to degraded communication quality, such as signal distortion and spurious emission.

To mitigate the degraded linearity, an RF front end power amplifier module can use a DC bias reference device (e.g., one or more non-RF transistors) to track the thermal behavior (e.g., heating or cooling) of the RF BJTs. For example, the DC bias reference device can be placed very close to the RF power amplifier such that the temperature change of the RF BJTs is reflected on the DC bias reference device, causing the physical properties of the DC bias reference device to change. The DC bias reference device thus can provide a bias control signal that changes according to the thermal behavior of the RF BJTs so as to modulate the bias voltage. The modulated bias voltage, possibly accompanied by a digital control signal, can compensate the shift of RF BJTs' transfer characteristics and reduce the degradation of linearity.

While the above mechanism can be helpful in tracking the thermal behavior of the RF BJTs, disposing the DC bias reference device close to the RF BJTs can lead to unwanted RF interference between the RF power amplifier and the DC bias reference device. For example, due to the close proximity of the RF power amplifier, the RF emissions from the RF power amplifier transistor can be captured by the DC bias reference device, leading to unwanted RF modulated bias voltage and/or current. Such unwanted bias voltage and/or current can cause signal distortion and RF noise in the RF power amplifier.

In view of the challenges above, implementations of this disclosure provide a thermally adjustable DC bias circuitry that places the DC bias reference device at a distance from the RF power amplifier. Instead of being directly thermally coupled to the RF BJTs, the DC bias reference device is thermally coupled to one or more heating elements configured to emulate the thermal behavior of the RF BJTs. The one or more heating elements generate little or no RF emission. Moreover, the one or more heating elements can be independently controlled by an external control signal to adjust their thermal behaviors. By keeping the distance large enough to avoid interference with the RF power amplifier, the DC bias reference device can still modulate the bias voltage to improve the linearity of the RF power amplifier, with improved RF signal quality and reduced noise within the RF power amplifier.

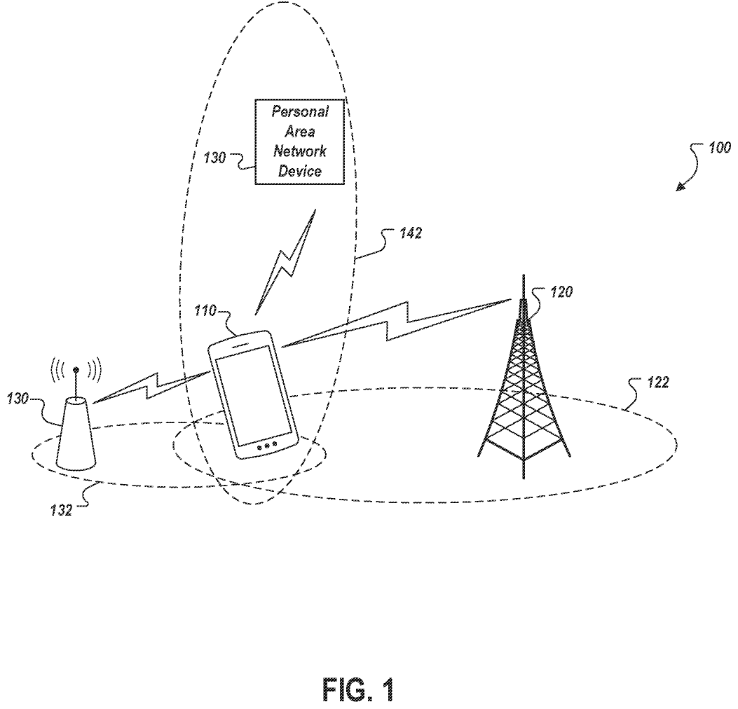

FIG. 1 is a schematic diagram of an example wireless communication system 100 including a wireless device 110 capable of communicating with one or more wireless communication networks. The one or more wireless communication networks with which the wireless device 110 is capable of communicating can include but is not limited to one or more cellular or wireless wide area networks (WWANs), one or more wireless local area networks (WLANs), one or more wireless personal area networks (WPANs), or a combination thereof.

In the example of FIG. 1, the wireless device 110 is communicating with at least one WWAN by way of at least one base station 120 and at least one WLAN by way of at least one access point 130. The at least one base station 120 can support bi-directional communication with wireless devices that are within its corresponding area of coverage 122. Similarly, the at least one access point 130 can support bi-directional communication with wireless devices that are within its corresponding area of coverage 132.

In some implementations, the at least one WWAN with which the at least one base station 120 is associated can be a fifth generation (5G) network among other generations and types of networks. In these implementations, the at least one base station 120 can be a 5G base station that employs orthogonal frequency-division multiplexing (OFDM) and/or non-OFDM and a transmission time interval (TTI) shorter than 1 ms (e.g. 100 or 200 microseconds), to communicate with wireless devices, such as wireless device 110. For example, the at least one base station 120 can take the form of one of several devices, such as a base transceiver station (BTS), a Node-B (NodeB), an evolved NodeB (eNB), a next (fifth) generation (NR) NodeB (gNB), a Home NodeB, a Home eNodeB, a site controller, an access point, a wireless router, a server, router, switch, or other processing entity with a wired or wireless network.

System 100 can use multiple channel access functionality, including for example schemes in which the at least one base station 120 and the wireless device 110 are configured to implement the Long Term Evolution wireless communication standard (LTE), LTE Advanced (LTE-A), and/or LTE Multimedia Broadcast Multicast Service (MBMS). In other implementations, the at least one base stations 120 and wireless device 110 are configured to implement UMTS, HSPA, or HSPA+ standards and protocols. Of course, other multiple access schemes and wireless protocols can be utilized. In some examples, one or more such access schemes and wireless protocols can correspond to standards that impose RF power amplifier linearity requirements.

In addition, and as shown in FIG. 1, the wireless device 110 is configured to communicate with one or more personal area network (PAN) devices/systems 130 (e.g., Bluetooth® or radio frequency identification (RFID) systems and devices) over one or more WPANs. The one or more PAN devices/systems 130 can support either one-way or bi-directional communication with wireless devices that are within its corresponding area of coverage 142.

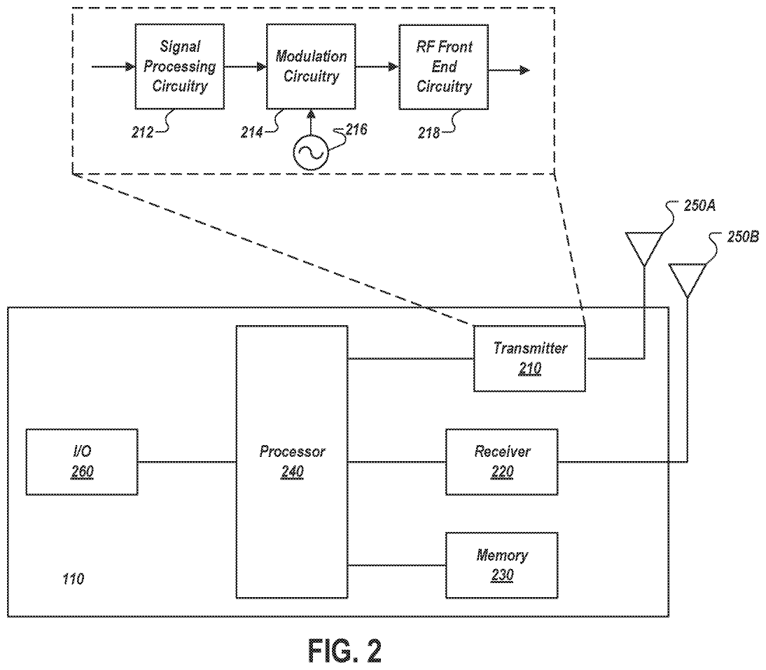

To communicate with one or both of the at least one base station 120 and the access point 130, the wireless device 110 can include singular or multiple transmitter and receiver components similar or equivalent to one or more of those described in further detail below with reference to FIG. 2 to support multiple communications with different types of access points, base stations, and other wireless communication devices.

Although FIG. 1 illustrates one example of a communication system, various changes can be made to FIG. 1. For example, the communication system 100 could include any number of wireless devices, base stations, access points, networks, or other components in any suitable configuration.

FIG. 2 is a block diagram that illustrates example details of the wireless device 110 that can implement the subject matter according to this disclosure. The wireless device 110 can, for example, be a mobile telephone, but can be other devices in further examples such as a desktop computer, laptop computer, tablet, hand-held computing device, automobile computing device and/or other computing devices. As shown in the figure, the wireless device 110 is shown as including at least one transmitter 210, at least one receiver 220, memory 230, at least one processor 240, and at least one input/output device 260. Here, only one transmitter and only one receiver are shown, but in many implementations, multiple transmitters and receivers are included to support multiple communications of different types at the same time. Each transmitter may employ the innovations of the present disclosure.

The processor 240 can implement various processing operations of the wireless device 110. For example, the processor 240 can perform signal generation, signal coding, signal analysis, data processing, power control, input/output processing, or any other functionality enabling the wireless device 110 to operate in a communication system, such as system 100 (FIG. 1). The processor 240 can include any suitable processing or computing device configured to perform one or more operations. For example, the processor 240 can include a microprocessor, microcontroller, digital signal processor, field programmable gate array, or application specific integrated circuit, or a combination of these devices.

The transmitter 210 can be configured to modulate data or other content, filter and amplify outgoing RF signals for transmission by at least one antenna 250A. In some implementations, the transmitter 210 can also be configured to amplify, filter and upconvert baseband or intermediate frequency (IF) signals to RFs signals before such signals are provided to the antenna 250A for transmission. The transmitter 210 can include any suitable structure for generating RF signals for wireless transmission. Additional aspects of the transmitter 210 are described in further detail below with reference to components 212-218 as depicted in FIG. 2.

The receiver 220 can be configured to demodulate data or other content received in incoming RF signals by at least one antenna 250B. In some implementations, the receiver 220 can also be configured to amplify, filter and frequency down convert RF signals received via the antenna 250B either to IF or baseband frequency signals prior to conversion to digital form and processing. The receiver 220 can include any suitable structure for processing signals received wirelessly.

Each of the antennas 250A and 250B can include any suitable structure for transmitting and/or receiving wireless RF signals. In some implementations, the antennas 250A and 250B can be implemented by way of a single antenna that can be used for both transmitting and receiving RF signals.

One or multiple transmitters 210, one or multiple receivers 220, and one or multiple antennas 250 could be used in the wireless device 110. For example, in one implementation, device 110 includes at least three transmitters 210 and at least three receivers 220 for communicating via at least a personal area network such as Bluetooth®, a Wi-Fi network such as an IEEE 802.11 based network, and a cellular network. Each transmitter 210 may employ the concepts of the present disclosure. Although shown as separate blocks or components, at least one transmitter 210 and at least one receiver 220 could be combined into a transceiver. Each transceiver may employ the concepts of the present disclosure. Accordingly, rather than showing a separate block for the transmitter 210 and a separate block for the receiver 220 in FIG. 2, a single block for a transceiver could have been shown.

The wireless device 110 further includes one or more input/output devices 260. The input/output devices 260 facilitate interaction with a user. Each input/output device 260 includes any suitable structure for providing information to or receiving information from a user, such as a speaker, microphone, keypad, keyboard, display, and/or touch screen.

In addition, the wireless device 110 includes at least one memory 230. The memory 230 stores instructions and data used, generated, and/or collected by the wireless device 110. For example, the memory 230 could store software or firmware instructions executed by the processor(s) 240 and data used to reduce or eliminate interference in incoming signals. Each memory 230 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, and the like.

In some implementations, the transmitter 210 can include signal processing circuitry 212, modulation circuitry 214, and RF front end circuitry 217. The signal processing circuitry 212 may include one or more circuits that are configured to process signals received as input (e.g. from processor 240). For example, the signal processing circuitry 212 may include a digital-to-analog converter (D/A), which converts a digital input (e.g. a digital signal from processor 240) into an analog signal, which is then provided to a low pass filter, which filters the analog signal and provides the filtered analog signal to the modulation circuitry 214. The modulation circuitry 214, in addition to receiving the filtered analog signal from the signal processing circuitry 212, can, in some implementations, also receive a signal from a local oscillator 216 for modulating or adjusting the frequency of the analog signal, e.g., from a first frequency to a second frequency that is higher than the first frequency. For instance, the modulation circuitry 214 can include a mixer that frequency up-converts the filtered analog signal from a relatively low frequency (e.g. baseband frequency, or an IF that is offset from the baseband frequency) to a relatively high frequency RF signal. Thus, a signal from the local oscillator 216 is used as a carrier signal in transmitter 210. Moreover, as shown in FIG. 2, transmitter 210 includes RF front end circuitry 217, which can include, e.g., amplification and filtering circuits that amplify and filter, respectively, the RF signal. The RF front end circuitry can also include a power amplifier that is configured to provide sufficient amplification of the signal to meet transmission requirements, as may be specified by wireless communication standards. Examples of such standards include those set forth by the 3rd Generation Partnership Project (3GPP), which is a group that develops standards for cellular telecommunications technologies, including radio access, core network, and service capabilities.

The RF signal amplified by the power amplifier may be filtered again by at least one additional filter downstream of the power amplifier before being provided as an output of the transmitter 210 to the at least one antenna 250A for wireless transmission. Such filter or filters can alternatively be provided upstream from the power amplifier in which case the output of the power amplifier is provided to the at least one antenna 250A for wireless transmission.

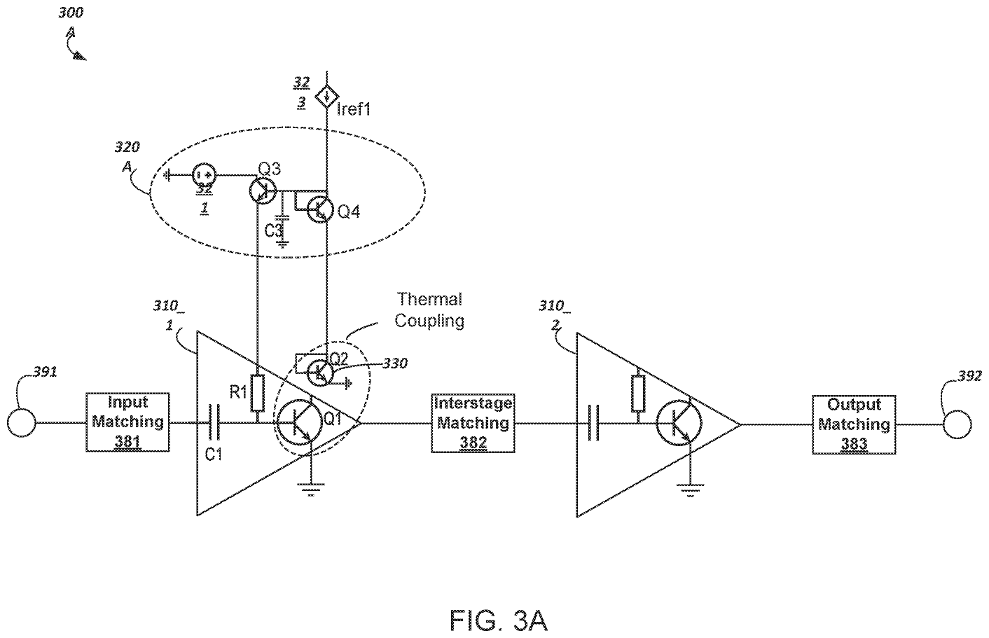

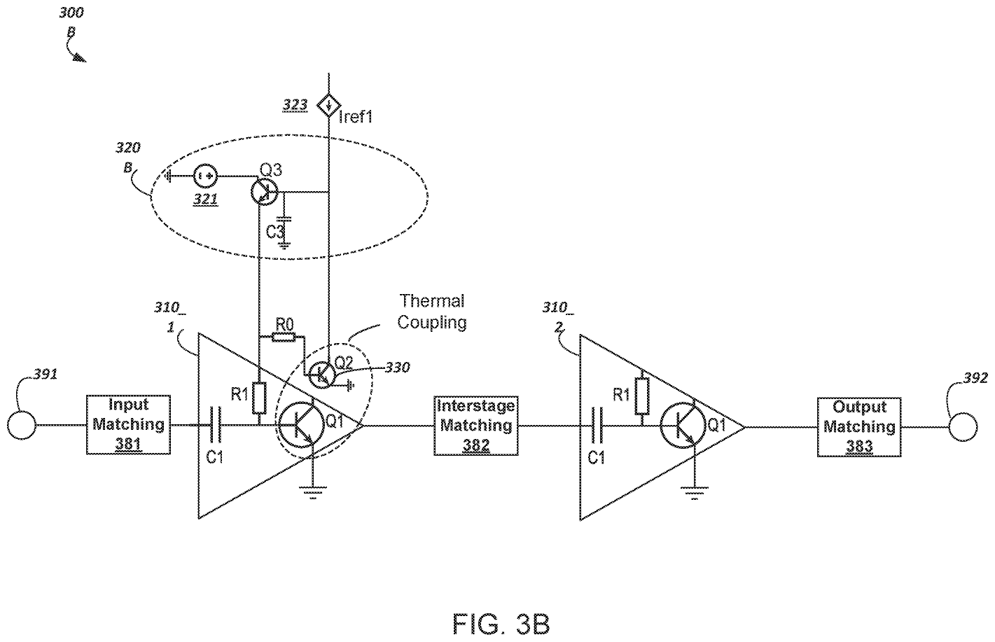

FIG. 3A is a schematic diagram of an example RF front end power amplifier module 300A where thermal tracking is realized by the coupling between a power amplifier and a DC bias reference device. The RF front end power amplifier module 300A can be implemented, e.g., as part of the RF front end circuitry 218 of FIG. 2. The RF front end power amplifier module 300A has two stages of power amplification between the input 391 and the output 392. Each stage has a power amplifier, 310_1 and 310_2. Each of the power amplifiers 310_1 and 310_2 is coupled with a DC bias circuit and a DC bias reference device. While the two stages may or may not have the same circuitry, the below description assumes that the two power amplifiers 310 and the corresponding DC bias circuits and DC bias reference devices are the same. Therefore, for the sake of brevity, the below description only describes the power amplifier 310_1 and its corresponding DC bias circuit 320A and DC bias reference device 330. The DC bias circuit and the DC bias reference device corresponding to the power amplifier 310_2 are also omitted from FIG. 3A. In addition, the RF front end power amplifier module 300A can have impedance matching circuitry, such as input matching circuitry 381, interstage matching circuitry 382, and output matching circuitry 383. While the RF front end power amplifier module 300A is shown to have two stages, other RF front end power amplifier modules can have more or fewer stages.

The RF power amplifier 310_1 can be, e.g., a class A, B, or C power amplifier, or an RF power amplifier of other types. As shown in FIG. 3A, the RF power amplifier 310_1 has one or more RF transistors Q1, coupled to other circuit components, such as the resistor R1 and the capacitor C1. The connection between Q1, R1, and C1 in FIG. 3A is for illustrative purpose only. One of ordinary skill in the art would understand that many other ways of connecting circuit components to form an RF power amplifier are available.

The power amplifier 310_1 is electrically coupled to the DC bias circuit 320A, which provides the power amplifier 310_1 with a DC bias voltage such that the one or more RF transistors Q1 are properly biased. As shown in FIG. 3A, the DC bias circuit 320A has a DC power source 321 that outputs a DC voltage, used as the DC bias voltage subject to the control of a bias control circuit 323. The bias control circuit 323 can be integrated with the DC bias circuit 320A or can be external to the DC bias circuit 320A.

The bias control circuit 323 can have, e.g., control logic that implements communication protocols according to the RF signal at the input 391. Based on the communication protocols, a the bias control circuit 323 can generate a bias control signal I_{ref1} and input the bias control signal I_{ref1} to the DC bias circuit 320A to control when and how much to apply the DC bias voltage. For example, when the RF power amplifier 310_1 operates in the pulse mode, the bias control signal I_{ref1} can assert shortly before the RF signal reaches the input 391, thereby activating, via components such as a coupling transistor Q3 and a capacitor C3, the RF power amplifier 310_1 when the RF signal reaches the RF power amplifier 310_1. Similarly, the bias control signal I_{ref1} can drop at a predetermined time, such that the RF power amplifier 310_1 deactivates according to a predetermined duty cycle of the pulse.

The proximity of the reference device 330 (in particular, Q2) to the one or more RF transistors Q1 can help reduce the unwanted impact on the linearity of the RF power amplifier 310_1 due to drastic and frequent temperature changes of the one or more RF transistors Q1. This can be achieved, e.g., by placing the DC bias reference device 330 close to the one or more RF transistors Q1 through to track the thermal behaviors of Q1 in order to modulate the DC bias voltage or current.

As shown in FIG. 3A, the DC bias reference device 330 has one or more DC bias reference transistors Q2, whose collector receives the bias control signal I_{ref1} via a transistor Q4. The one or more DC bias reference transistors Q2 are sensitive to changes of ambient temperature. By placing the DC bias reference device 330 very close to the one or more RF transistors Q1, the temperature changes on Q1 are reflected on Q2 via thermal coupling. That is, the heating or cooling of Q1 causes Q2 to heat or cool accordingly, thereby causing the transfer characteristic of Q2 to shift. This mechanism can be referred to as thermal tracking. The shift of transfer characteristic of Q2 in turn causes bias circuitry 320A to change the bias voltage applied to Q1. As such, the DC bias voltage applied to the RF power amplifier 310_1 takes into account not only the communication protocol of the RF signal but also the thermal behavior of the one or more RF transistors Q1.

FIG. 3B is another schematic diagram of an example RF front end power amplifier module 300B where thermal coupling occurs between a power amplifier and a DC bias reference device. The RF front end power amplifier module 300B can be implemented, e.g., as part of the RF front end circuitry 218 of FIG. 2. The circuit illustrated in FIG. 3B is substantially the same as that illustrated in FIG. 3A, except that the RF front end power amplifier module 300B does not have the transistor Q4 in the DC bias circuit 320B and that the base of the transistor Q2 is connected to the bias voltage via a resistor R0. The connection between the DC bias reference device 330 and the DC bias circuit 320A is commonly referred as “open loop” bias, whereas the connection between the DC bias reference device 330 and the DC bias circuit 320B is commonly referred as “closed loop” bias. Notwithstanding this difference, the mechanisms of biasing the RF power amplifier 310_1 and controlling the DC bias voltage are substantially the same between the RF front end power amplifier modules 300A and 300B. Therefore, the description of the latter is omitted for brevity.

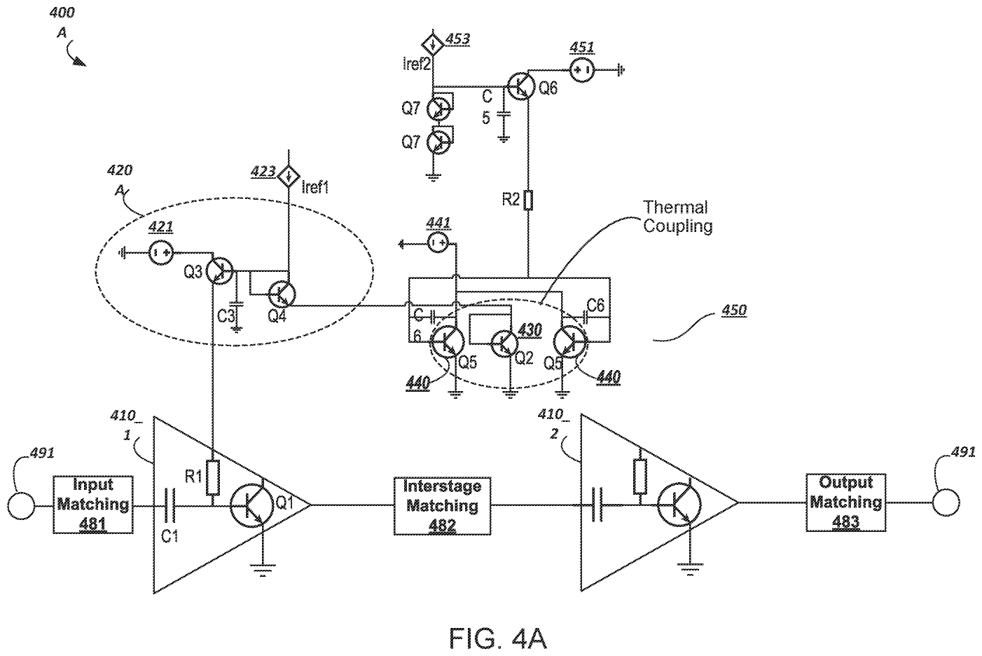

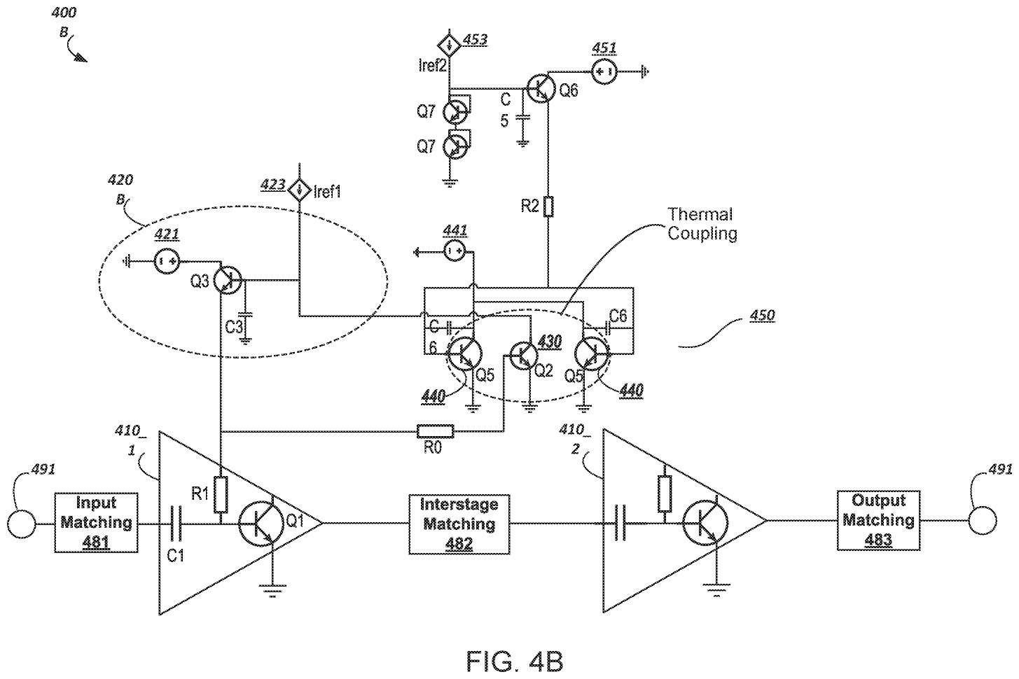

While ideally thermal coupling Q1 with Q2 in FIGS. 3A and 3B can improve the dynamic linearity of the RF power amplifier 310_1, placing Q2 very close to Q1 can lead to RF interference between the RF power amplifier 310_1 and the DC bias reference device 330, causing signal distortion and degradation in other RF performance metrics. To mitigate these unwanted effects and further provide flexibility to adjust the thermal behavior of the DC bias reference devices, one or more implementations provide a different approach. Example implementations are described below with reference to FIGS. 4A and 4B.

FIG. 4A is a schematic diagram of an example RF front end power amplifier module 400A, according to some implementations. The RF front end power amplifier module 400A can be implemented, e.g., as part of the RF front end circuitry 218 of FIG. 2. Similar to the illustration in FIG. 3A, the RF front end power amplifier module 400A has two stages of power amplification between the input 491 and the output 492, as well as impedance matching circuitry 481, 482, and 483. Each stage has an RF power amplifier, 410_1 and 410_2, which may be similar to RF power amplifiers 310_1 and 310_2 illustrated in FIGS. 3A and 3B. For brevity, the below description only focuses on the RF power amplifier 410_1 and its peripheral circuitry.

At the outset, the DC bias circuit 420A of the RF front end power amplifier module 400A is similar to the DC bias circuit 320A in FIG. 3A. Specifically, the DC bias circuit 420A has a DC power source 421 electrically coupled to bias control circuit 423 via components such as Q3 and C3. The bias control circuit 423 can be integrated with the DC bias circuit 420A or can be external to the DC bias circuit 420A. The bias control circuit 423 generates a bias control signal I_{ref1} and inputs the bias control signal I_{ref1} to the DC bias circuit 420A via, e.g., a bias control input. The bias control signal I_{ref1} controls, via Q3, the DC bias voltage applied to the RF power amplifier 410_1. In addition, the DC bias circuit 420A and the DC bias reference device 430 (described below) adopt an “open loop bias” connection similar to FIG. 3A.

The RF front end power amplifier module 400A has a DC bias reference device 430. Similar to the DC bias reference device 330 in FIGS. 3A and 3B, the DC bias reference device 430 has one or more DC bias reference transistors Q2. However, different from the DC bias reference device 330, the DC bias reference device 430 is located relatively far away from the one or more RF transistors Q1 to avoid RF interference imposed by the RF power amplifier 410_1. Instead of having direct thermal coupling with Q1, the thermal behavior of the DC bias reference device 430 can be adjustable through a bias control signal I_{ref2}.

Compared with the position of the DC bias reference device 330, the relatively large distance between the DC bias reference device 430 and the RF power amplifier 410_1 can make the thermal coupling between the two weak and non-detectable. Therefore, in order for the DC bias reference device 430 to track the thermal behavior of the one or more RF transistors Q1, the RF front end power amplifier module 400A implements a thermal tracking circuit 450 that emulates the thermal behavior of the one or more RF transistors Q1. By placing the DC bias reference device 430 very close to the thermal tracking circuit 450, the temperature changes on the thermal tracking circuit 450 are reflected on Q2 via thermal coupling. As such, the DC bias reference device 430 can still track, though indirectly, the thermal behavior of the one or more RF transistors Q1. Furthermore, the thermal tracking can be readily and independently adjusted via the bias control signal I_{ref2} to a level that produces desired dynamic linearity performances.

The thermal tracking circuit 450 has one or more heating elements 440, such as transistors Q5. The collector of each transistor Q5 receives a DC voltage from a DC power source 441. The base of each transistor Q5 is biased, via components such as resistor R2, with a DC bias voltage from a DC power source 451. The thermal tracking circuit 450 receives a thermal tracking control signal I_{ref2} from a thermal tracking control circuit 453, which can be integrated with the thermal tracking circuit 450 or can be external to thermal tracking circuit 450. The thermal tracking control signal I_{ref2}, which can be an analog signal in some implementations, modulates, via transistor Q6, the DC bias voltage applied on the base of transistors Q5. The thermal tracking circuit 450 can also include components such as one or more transistors Q7 and/or one or more capacitors C6.

As discussed previously, the thermal tracking circuit 450 simulates the thermal behavior of the one or more RF transistors Q1. To this end, the thermal tracking control circuit 453 can control the thermal tracking control signal I_{ref1}, to be synchronized with the bias control signal I_{ref1}. For example, both the bias control signal I_{ref2} and the thermal tracking control signal I_{ref2} can be synchronized with a pulse signal. The pulse signal can serve as a trigger signal, which asserts at a predetermined time before an incoming RF signal reaches the RF front end power amplifier module 400A. As such, when the bias control signal I_{ref1} modulates the DC bias voltage on the one or more RF transistors Q1 to activate Q1 (e.g., cause Q1 to heat up) or deactivate Q1 (e.g., cause Q1 to cool down), the thermal tracking control signal I_{ref2} contemporaneously modulates the DC bias voltage on the heating elements 440 to activate or deactivate the transistors Q5. Because the one or more DC bias reference transistors Q2 are located very close to (e.g., surrounded by or sandwiched by) the heating elements 440, the temperature changes on the heating elements 440 are reflected on the one or more DC bias reference transistors Q2 via thermal coupling. As such, the transfer characteristic of Q2 shifts according to the heating and cooling of the one or more RF transistors Q1, even if there is no detectable thermal coupling directly between Q2 and Q1. Similar to the mechanism described with reference to FIG. 3A, the shift of transfer characteristic of Q2 provides a thermally compensated bias voltage through components such as Q3 and Q4 to power amplifier Q1.

The thermal tracking mechanism described with reference to FIG. 4A allows the DC bias reference device 430 to be located relatively far away from the RF power amplifier 410_1, thereby reducing RF interference between the two components. This mechanism thus offers great flexibility for circuit designers to balance thermal tracking efficiency and RF power amplifier linearity against RF interference. A circuit designer can determine the distance between the thermal tracking circuit 450 (in particular the DC bias reference device 430 surrounded by the heating elements 440) and the RF power amplifier 410_1 based on a variety of factors. For example, because the strength of RF interference may correlate with the frequency of the RF signal, the designer can determine the distance based on the operating frequency of the input RF signal. Also, because strong thermal radiation may correlate with strong RF interference, the designer can determine the distance based on visual presentation of measured thermal radiation of the one or more RF transistors Q1. Additionally, the designer can determine the distance taking into account a size constraint of the circuit and/or the physical layout of the circuit. Considering these factors, the designer can determine the distance such that the RF interference is within a tolerable range (e.g., less than a threshold level) for the RF front end power amplifier module to operate properly.

The thermal tracking mechanism described with reference to FIG. 4A also offers great adjustability of the biasing of the one or more RF transistors Q1 by, e.g., independently tuning the bias reference device's thermal tracking behavior. For example, a designer can adjust the magnitude of the thermal tracking control signal I_{ref2} via, e.g., a mobile industry processor interface (MIPI) on the thermal tracking control circuit 453. This allows the designer to tune up the thermal coupling between the heating elements 440 and the DC bias reference device 430 to find a desired level of thermal coupling with little or no RF interference from the one or more RF transistors Q1. Such tune-up can be conveniently done by software in a laboratory environment without changing hardware assemblies.

FIG. 4B is a schematic diagram of an example RF front end power amplifier module 400B, according to some implementations. The RF front end power amplifier module 400B can be implemented, e.g., as part of the RF front end circuitry 218 of FIG. 2. The circuit illustrated in FIG. 4B is substantially the same as that illustrated in FIG. 4A, except that FIG. 4B illustrates a “closed loop bias” connection, as opposed to the “open loop bias” connection illustrated by FIG. 4A. Notwithstanding this difference, the mechanisms of biasing the RF power amplifier 410_1, controlling the DC bias voltage of the RF power amplifier 410_1, and emulating the heating and cooling of the one or more RF transistors Q1 are substantially the same between the RF front end power amplifier modules 400A and 400B. Therefore, the description of the latter is omitted for brevity.

While the RF front end power amplifier modules 400A and 400B use transistors Q5 as heating elements 440, other types of circuit components, such as resistors, can be used in other implementations, so long as the heating elements can be configured with similar thermal reactions to the thermal tracking control signal I_{ref2}.

In addition, while the DC power sources 421, 441, and 451 are illustrated as separate instances and can vary in their output DC voltage, the DC power sources 421, 441, and 451 can be implemented as a single DC power source with the same output DC voltage. In some implementations, the DC power sources 421, 441, and 451 can include power pins that receive power from external power sources.

Furthermore, with respect to circuit components such as R0, R1, R2, C1, C3, C5, C6, Q3, Q6, and Q7, some implementations can have more or fewer instances of these components. For example, while FIGS. 4A and 4B illustrate two instances of transistors Q7, some implementations can have only one instance or more than two instances of Q7. Likewise, while FIGS. 4A and 4B illustrate a single instance of R2 that connects the emitter of Q6 and the base of C5, some implementations can have more or fewer instances of R2, and can have other resistive, capacitive, or inductive components in addition to or in lieu of R2.

Additionally, while FIGS. 4A and 4B illustrate the various transistors Q1, Q2, Q3, Q4, Q5, Q6, and Q7 as BJTs of the NPN type, some implementations can have some or all of these transistors of PNP type. Some implementations can also use other types of semiconductors devices in lieu of some or all of these BJTs.

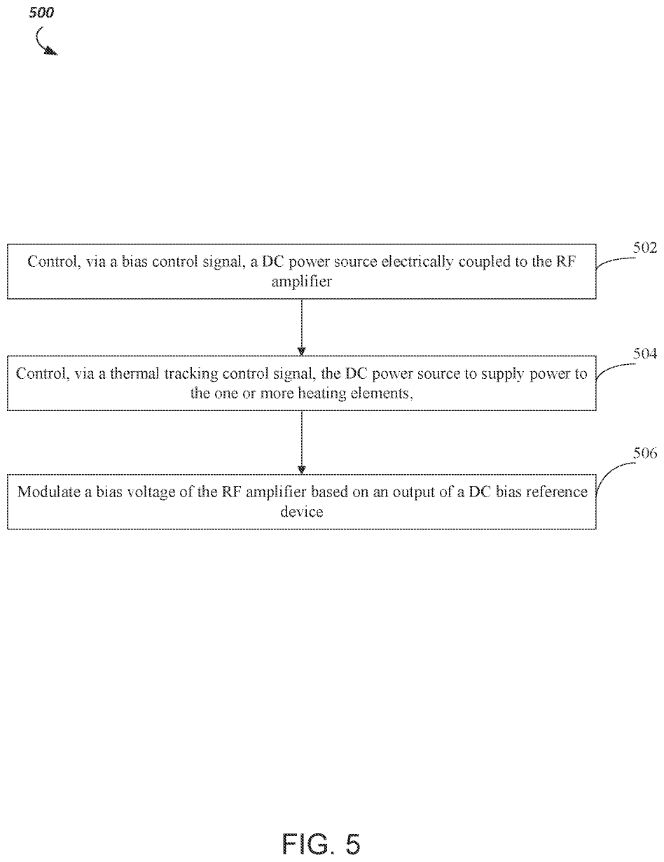

FIG. 5 is a flowchart of an example method 500, according to some implementations. For clarity of presentation, the description that follows generally describes the method 500 in the context of the other figures in this description. For example, the method 500 can be performed by circuitry of the wireless device 110 of FIG. 1, the RF front end power amplifier module 400A of FIG. 4A, or the RF front end power amplifier module 400B of FIG. 4B. It would be understood that the method 500 can be performed, for example, by any suitable system, environment, software, hardware, or a combination of systems, environments, software, and hardware, as appropriate. In some implementations, various steps of the method 500 can be run in parallel, in combination, in loops, or in any order.

At 502, the method 500 involves controlling, via a bias control signal, a DC power source electrically coupled to the RF amplifier. The controlling of the DC power source can be similar to the controlling of the DC power source 421 via the thermal tracking control signal I_{ref1}, as described with reference to FIGS. 4A and 4B.

At 504, the method 500 involves controlling, via a thermal tracking control signal, the DC power source to supply power to the one or more heating elements. In some implementations, the thermal tracking control signal controls a thermal behavior of the one or more heating elements, similar to the controlling of the thermal behavior of the heating elements 440 via the thermal tracking control signal I_{ref2}, as described with reference to FIGS. 4A and 4B.

At 506, the method 500 involves modulating a bias voltage of the RF amplifier based on an output of a DC bias reference device. In some implementations, the one or more heating elements are arranged to heat the DC bias reference device when the one or more heating elements are activated. Also, the DC bias reference device is located at a distance from one or more RF transistors of the RF amplifier such that RF interference between the one or more RF transistors and the DC bias reference device is below a threshold interference during operation of the circuit. The modulation of the bias voltage of the RF amplifier can be similar to the modulation of the bias voltage of the RF power amplifier 410_1, as described with reference to FIGS. 4A and 4B.

While features described above are primarily implemented by wireless devices, these features can likewise be implemented by access nodes, base stations, or other types fixed or portable wireless communication equipment and/or infrastructure. For example, a base station in communication with a cellular phone can have RF front end circuitry that implements the above-described features with respect to thermally adjustable DC bias circuit.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system modules and components in the implementations described above should not be understood as requiring such separation in all implementations, and it should be understood that the described program components and systems can generally be integrated together in a single software product or packaged into multiple software products.

In addition, techniques, systems, subsystems, and methods described and illustrated in the various implementations as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A circuit, comprising:
a radio frequency (RF) amplifier comprising one or more RF transistors;
a direct current (DC) power source electrically coupled to the RF amplifier;
a bias control input that receives a bias control signal from a bias control circuit, wherein the bias control input is electrically coupled to the DC power source; and
a thermal tracking circuit located at a distance from the one or more RF transistors such that RF interference between the one or more RF transistors and the thermal tracking circuit is below a threshold interference during operation of the circuit, the thermal tracking circuit comprising
one or more heating elements,
a thermal tracking control circuit electrically coupled to the DC power source and to the one or more heating elements, wherein the thermal tracking control circuit is configured to generate a thermal tracking control signal that controls a thermal behavior of the one or more heating elements, and
a DC bias reference device, wherein the one or more heating elements are arranged to heat the DC bias reference device when the one or more heating elements are activated, and wherein the DC bias reference device is electrically coupled to the bias control input and configured to modulate a bias voltage of the RF amplifier.

2. The circuit of claim 1,
wherein the bias control signal is synchronized with the thermal tracking control signal.

3. The circuit of claim 1, wherein the bias control signal and the thermal tracking control signal are synchronized with a pulse signal.

4. The circuit of claim 1,
wherein the one or more heating elements comprise two or more heating transistors, and
wherein the DC bias reference device is surrounded by the two or more heating transistors.

5. The circuit of claim 1,
wherein the DC power source is electrically coupled to the RF amplifier via a coupling transistor, and
wherein the coupling transistor is controlled by the bias control signal.

6. The circuit of claim 1, wherein the DC bias reference device comprises a DC bias reference transistor.

7. The circuit of claim 1, wherein the distance is determined based at least on an operating frequency of the RF amplifier.

8. The circuit of claim 1, wherein the distance is determined based at least on a thermal radiation of the one or more RF transistors.

9. The circuit of claim 1, wherein the distance is determined based at least on a size constraint of the circuit.

10. The circuit of claim 1, wherein the bias control circuit is configured to control the DC power source to provide the bias voltage at a predetermined time before the RF amplifier receives an RF signal.

11. A method for tracking a thermal behavior of a radio frequency (RF) amplifier in a circuit, the method comprising:
controlling, via a bias control signal, a direct current (DC) power source electrically coupled to the RF amplifier;
controlling, via a thermal tracking control signal, the DC power source to supply power to one or more heating elements, wherein the thermal tracking control signal controls a thermal behavior of the one or more heating elements; and
modulating a bias voltage of the RF amplifier based on an output of a DC bias reference device, wherein the one or more heating elements are arranged to heat the DC bias reference device when the one or more heating elements are activated, and wherein the DC bias reference device is located at a distance from one or more RF transistors of the RF amplifier such that RF interference between the one or more RF transistors and the DC bias reference device is below a threshold interference during operation of the circuit.

12. The method of claim 11,
wherein the bias control signal and the thermal tracking control signal are synchronized with a pulse signal.

13. The method of claim 11,
wherein the one or more heating elements comprise two or more heating transistors, and
wherein the DC bias reference device is surrounded by the two or more heating transistors.

14. The method of claim 11,
wherein the DC power source is electrically coupled to the RF amplifier via a coupling transistor, and
wherein the coupling transistor is controlled by the bias control signal.

15. The method of claim 11, wherein the DC bias reference device comprises a DC bias reference transistor.

16. The method of claim 11, further comprising:
determining the distance based at least on an operating frequency of the RF amplifier.

17. The method of claim 11, further comprising:
determining the distance based at least on a thermal radiation of the one or more RF transistors.

18. The method of claim 11, further comprising:
determining the distance based at least on a circuit size constraint.

19. The method of claim 11, wherein the bias control signal controls the DC power source to provide the bias voltage at a predetermined time before the RF amplifier receives an RF signal.

20. An apparatus comprising a plurality of amplification stages, wherein each amplification stage comprises:
a radio frequency (RF) amplifier comprising one or more RF transistors;
a direct current (DC) power source electrically coupled to the RF amplifier;
a bias control input that receives a bias control signal from a bias control circuit, wherein the bias control input is electrically coupled to the DC power source; and
a thermal tracking circuit located at a distance from the one or more RF transistors such that RF interference between the one or more RF transistors and the thermal tracking circuit is below a threshold interference during operation of the circuit, the thermal tracking circuit comprising
one or more heating elements,
a thermal tracking control circuit electrically coupled to the DC power source and to the one or more heating elements, wherein the thermal tracking control circuit is configured to generate a thermal tracking control signal that controls a thermal behavior of the one or more heating elements, and
a DC bias reference device, wherein the one or more heating elements are arranged to heat the DC bias reference device when the one or more heating elements are activated, and wherein the DC bias reference device is electrically coupled to the bias control circuit and configured to modulate a bias voltage of the RF amplifier.
